(19) United States
(12) Patent Application Publication
(10) Pub. No.: US 2010/0123206 A1
(43) Pub. Date: May 20, 2010

(54) METHODS OF FABRICATING FIELD EFFECT TRANSISTORS INCLUDING TITANIUM NITRIDE GATES OVER PARTIALLY NITRIDED OXIDE AND DEVICES SO FABRICATED

(75) Inventor: Michael W. Dennen, Wake Forest, NC (US)

Correspondence Address: MYERS BIGEL SIBLEY & SAJOVEC, PO BOX 37428, RALEIGH, NC, 27627, US

(73) Assignee: Thunderbird Technologies, Inc.

(21) Appl. No.: 12/617,938

(22) Filed: Nov. 13, 2009

Related U.S. Application Data
(60) Provisional application No. 61/115,841, filed on Nov. 18, 2008.

(51) Int. Cl. H01L 29/78; H01L 21/28

(52) U.S. Cl. 257/412; 438/592; 257/E21.19; 257/E29.255

(57) ABSTRACT

A gate of an integrated circuit field effect transistor is fabricated by fabricating a gate insulating layer on an integrated circuit substrate, fabricating a metal nitride layer on the gate insulating layer, annealing the metal nitride layer in a nitridizing ambient and fabricating a cap on the metal nitride layer that has been annealed. Thereafter, the cap on the metal nitride layer may be etched to expose sidewalls thereof and another anneal in a nitridizing ambient may take place. Related integrated circuit field effect transistors are also described.

### CROSS REFERENCE TO RELATED APPLICATION

This application claims the benefit of provisional Application No. 61/115,841, filed Nov. 18, 2008, entitled Field Effect Transistors Including Titanium Nitride (TiN) Gates Over Partially Nitrified Oxide (PNO) and Methods of Fabricating Same, the disclosure of which is hereby incorporated herein by reference in its entirety as if set forth fully herein.

### BACKGROUND OF THE INVENTION

This invention relates to integrated circuit devices and fabrication methods and, more particularly, to integrated circuit field effect transistors and fabrication methods therefor.

Field Effect Transistors (FETs), often referred to as Metal Oxide Semiconductor FETs (MOSFETs), MOS devices and/or Complementary MOS (CMOS) devices, are widely used in integrated circuit devices, including logic, memory, processor and other integrated circuit devices. One widely investigated FET is the Fermi-EFT, that is described, for example, in U.S. Pat. Nos. 4,984,043; 4,990,974; 5,151,759; 5,194,923; 5,222,039; 5,367,186; 5,369,295; 5,371,396; 5,374,836; 5,438,007; 5,440,160; 5,525,822; 5,543,654; 5,698,884; 5,786,620; 5,814,869; 5,885,876; and 6,555,872, and U.S. Patent Application Publication Nos. US 2006/0138548 and US 2007/0001199, assigned to Thunderbird Technologies, Inc., the assignee of the present invention, the disclosures of all of which are incorporated herein by reference in their entirety as if set forth fully herein.

Fermi-FET transistors have been well explored by Thunderbird Technologies and others for a number of years, and have been found to perform well at geometries where the high threshold produced by the counter-doped polysilicon gate is small compared to the power supply voltage V_{dd}. In the deep sub-micron regime however, the classical implementation of the transistor may result in poor performance relative to standard CMOS. In order to reduce the threshold voltage, the gate work function may be moved toward mid band energy.

Titanium Nitride (TiN) would be an excellent choice for a Fermi-FET gate since it produces a work function midway between the band edges of the silicon substrate, allowing a single material to serve as both the P and N-Channel gates. TiN would also be an excellent choice for a gate of a conventional deep sub-micron MOSFET using, for example, fully depleted SOI technology for at least the same reasons. Much prior work has been devoted to produce a nitrided metal gate over SiO₂ or Partially Nitrided Oxide (PNO). However, to date these efforts appear to have been unsuccessful at major CMOS companies.

### SUMMARY OF THE INVENTION

Fabrication methods according to various embodiments of the invention can provide one or two anneal steps that can permit the production of high-quality TiN (or other nitrided metal) gates over thin PNO dielectrics without the need to lower reliability or to increase the interface state density Dᵢₜ or gate leakage. Gate structures also may be provided as described below.

### BRIEF DESCRIPTION OF THE DRAWINGS

FIG. 1 is a cross-sectional view of an integrated circuit field effect transistor.

FIG. 2 is a micrograph illustrating defects that may occur during conventional gate fabrication processes.

FIG. 3 is a micrograph illustrating reduction of the defects of FIG. 2 according to various embodiments described herein.

FIG. 4 is a micrograph illustrating other defects in conventional gate fabrication processes.

FIG. 5 is a micrograph illustrating structural differences that can be brought about by various embodiments of the invention.

FIG. 6 is a flowchart of operations that can be performed to fabricate an integrated circuit field effect transistor gate according to various embodiments of the invention.

FIG. 7 graphically illustrates gate leakage vs. gate voltage using conventional methods and methods according to various embodiments described herein.

FIG. 8 graphically illustrates lifetime results for transistors that are fabricated according to various embodiments described herein.

FIG. 9 graphically illustrates lifetime results for various other transistors that are fabricated according to various embodiments described herein.

### DETAILED DESCRIPTION

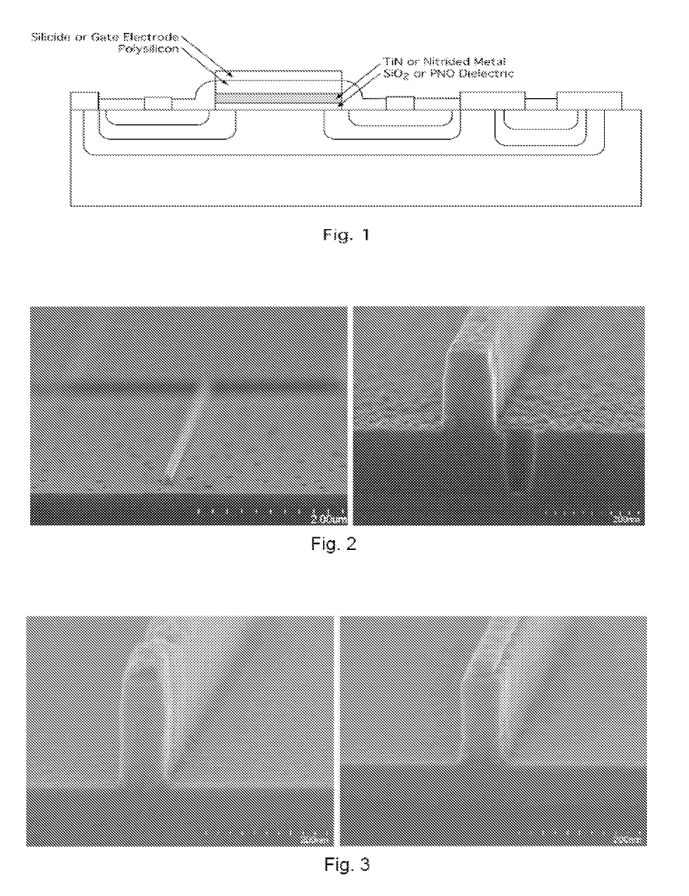

FIG. 1 illustrates a standard Fermi-LET transistor with a nitrided metal film at the bottom of the gate electrode. A standard. MOSFET structure with a nitrided metal film may also be provided in other embodiments. Such a structure has been proposed in the literature, but does not appear to have been realized with high reliability, low trapped charge and/or low dielectric leakage. However, according to various embodiments of the invention, one or more anneals may be performed at specific points in the fabrication process to reduce or eliminate these difficulties and allow the production of nitrided metal gate stacks at quality levels needed by current products.

One difficulty generally encountered in using nitrided metals in the gate stack is the tendency of the metal atoms to react with the underlying oxide in subsequent high temperature steps. e.g. Rapid Thermal Anneal (RTA) or Spike Anneals, that are used to activate dopant atoms. These defects are shown in FIG. 2, where a high temperature anneal was performed before the gate etch. This allowed the etch chemistry to decorate the regions where un-nitrided metal atoms reacted with the dielectric. These sites are shown as pits where the reacted dielectric was removed.

These defect sites can be at least partially and even completely removed by performing a low temperature anneal in a nitridizing ambient (e.g. NH₃) after the TiN is deposited but before the polysilicon cap is in place. Some embodiments can use ammonia at about 700° C. and about 30 Torr for about 60 seconds. Experimental results are shown in FIG. 3. More specifically, FIG. 3 shows the TiN gates using the ammonia anneal. The pictures show pre (left) and post (right) BOE etch. Other nitridizing ambients, temperatures, pressures and/or times may be used. For example, in other embodiments, N₂O, NO, N₂ and/or CN gas or other nitriding gasses may be used, for between about 5 sec and about 400 sec at between about 500° C. and 900° C., between about 760 Torr and 1 Torr, with or without plasma activation.

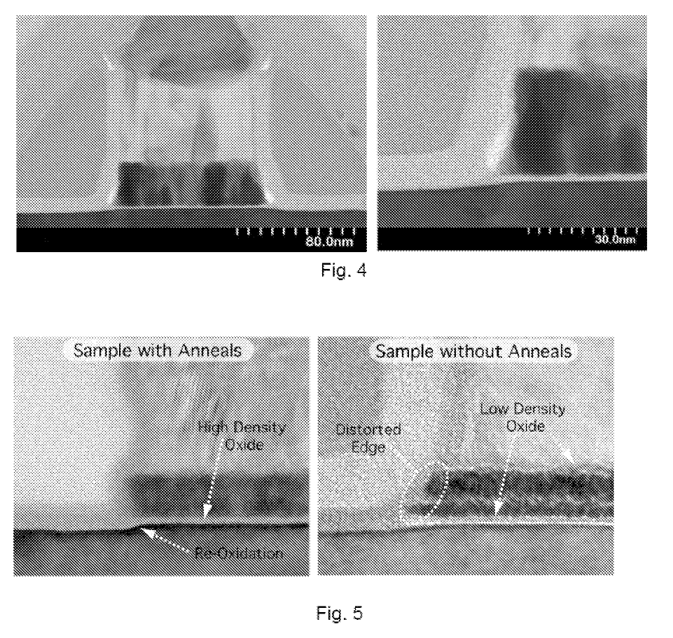

A second reliability problem generally occurs during the gate etch itself. The exposed nitrided metal at the edge of the gate structure can have a percentage of non-nitridized metal present due to the etch itself. Through subsequent process steps this metal can react with the underlying gate oxide, or it can become oxidized itself destroying the local dielectric strength. This is shown in FIG. 4.

In particular, FIG. 4 shows a STEM cross section of a TiN gate processed without a post etch anneal. Note the change in the edge angle of the TiN film and the light colored low density regions outside of the metal film layer. This appears due to reaction with the capping film following the gate etch. These changes can lead to poor dielectric strength between the gate and the adjacent diffusions and high gate leakage.

This problem can be reduced or eliminated through the use of a low temperature anneal in an ambient that will oxidize the exposed silicon while reducing any elemental titanium to TiN. Various embodiments of the invention have discovered that a low pressure anneal can accomplish this. Specifically, in some embodiments, about 30 seconds of N₂O/NH₃/He 50/300/1615 seem at 400° C. and 7 Torr with an applied 100 W RF power was used. Experimental results of this test are shown in FIG. 5. However, other gases, ratios, pressures, temperatures and/or times may be used. For example, in other embodiments, N₂, CN and/or other nitriding gasses may be used, for between about 10 sec and about 400 sec at between about 200° C. and 500° C. between about 1 Torr and 760 Torr and between about 20 W and about 5 kW.

Analysis of FIG. 5 also shows structural differences that can be brought about by various embodiments of the invention. First, the TiN edge profile remains vertical, as was the case after gate etching. However, the gate dielectric below the TiN shows significantly higher density (darker color) as does the TiN to polysilicon interface above the film. This is due to the lack of reaction between the titanium and the silicon.

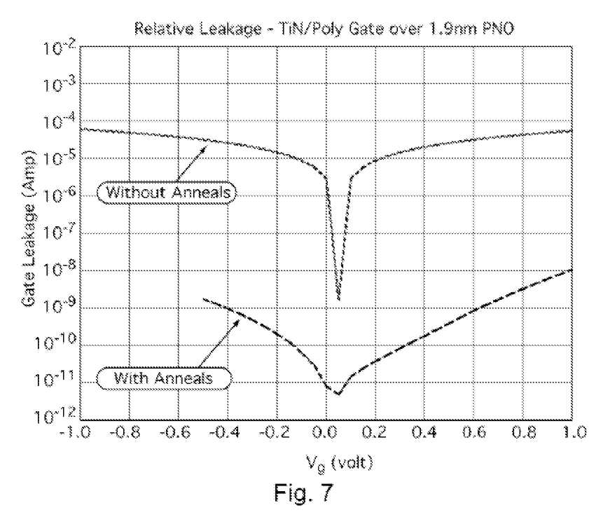

Also illustrated is the edge re-oxidation that occurs in the substrate under the gate edge. This can significantly improve leakage and/or reliability of the transistors as shown in FIGS. 7, 8, and 9.

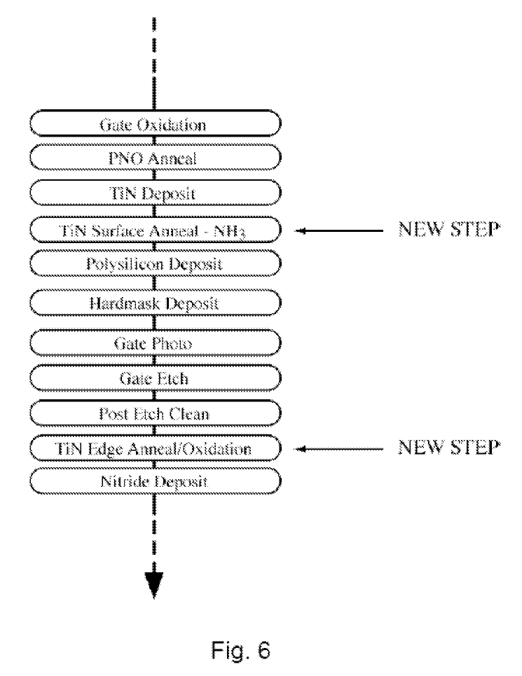

FIG. 6 is a representation of a segment of the CMOS process flow showing the locations of these two new anneal steps according to various embodiments of the invention. Either or both steps may be used.

Inclusion of both of these anneals can create a significant improvement in gate leakage and reliability, which can allow the use of nitrided metal films directly on SiO₂ or PNO gate dielectrics, and can reduce or eliminate the need for far more complex high-k dielectric films.

FIG. 7 shows the measured gate current from transistors of identical size. Supply voltage V_{dd} is 0.05V, for both curves. Two anneals according to various embodiments of the invention are shown to result in a reduction in gate leakage of at least about 5 orders of magnitude. The improved leakage is similar to poly only gates.

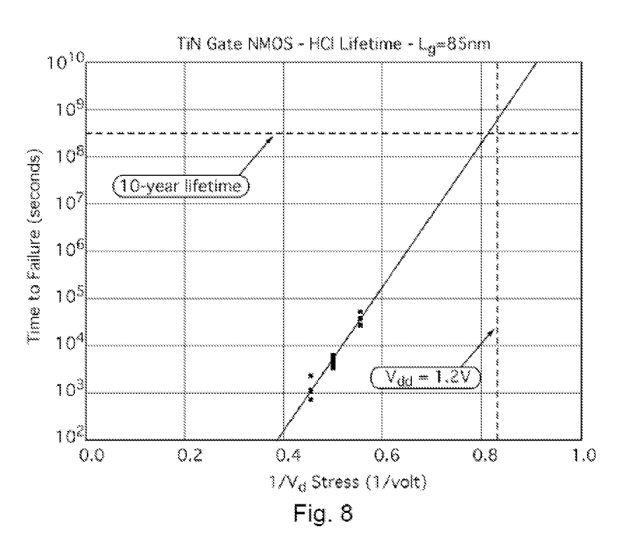

FIG. 8 shows the results obtained by testing the HCI Lifetime on short channel NMOS transistors manufactured utilizing the two anneal cycles. Testing was performed according to JEDEC recommendations. The results clearly show that the transistors including a TiN film over PNO clearly meet the industry standard of 10 years.

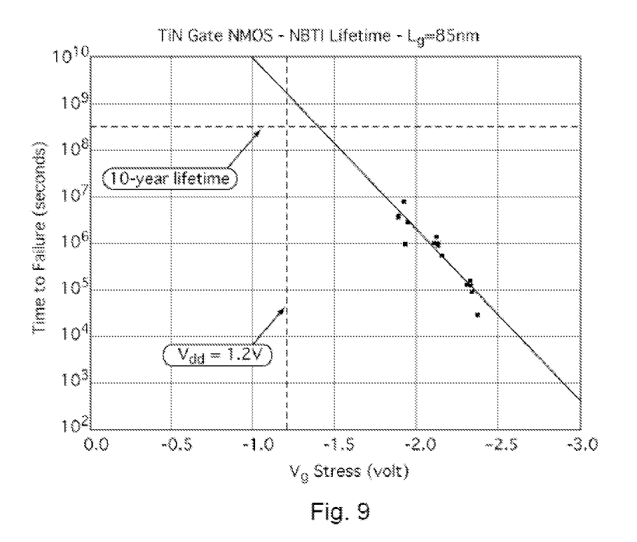

FIG. 9 shows results obtained by testing the NBTI Lifetime on short channel PMOS transistors manufactured utilizing the two anneal cycles. Testing was performed according to JEDEC recommendations. The results clearly show that the transistors including a TiN film over PNO clearly meet the industry standard of 10 years.

The combination of anneals according to various embodiments of the invention can produce better than industry standard lifetime for both transistor types using nitrided metal films directly on PNO.

The present invention has been described herein with reference to the accompanying drawings, in which exemplary embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Moreover, each embodiment described and illustrated herein includes its complementary conductivity type embodiment as well. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As Used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items and may be abbreviated as “/”.

Embodiments of the invention are described herein with reference to illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. All publications, patent applications, patents, and other references mentioned herein are incorporated by reference in their entirety.

Accordingly, many different embodiments stem from the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A method of fabricating an integrated circuit field effect transistor gate, the method comprising:
fabricating a gate insulating layer on an integrated circuit substrate;
fabricating a metal nitride layer on the gate insulating layer:
annealing the metal nitride layer in a nitridizing ambient; and
fabricating a cap on the metal nitride layer that has been annealed in the nitridizing ambient.

2. A method according to claim 1, wherein the nitridizing ambient comprises a first nitridizing ambient, the method further comprising:
etching the cap and the metal nitride layer that has been annealed in the first nitridizing ambient to expose sidewalls thereof; and
annealing a sidewall of the metal nitride layer in a second nitridizing ambient.

3. A method according to claim 1 wherein annealing the metal nitride layer in a nitridizing ambient comprises annealing the metal nitride layer in an ambient that comprises NH₃.

4. A method according to claim 3 wherein annealing the metal nitride layer in an ambient that comprises NH₃ is performed at about 700° C. and about 30 Torr for about 60 seconds.

5. A method according to claim 1 wherein annealing the metal nitride layer in a nitridizing ambient comprises annealing the metal nitride layer in an ambient that comprises N₂O, NO, N₂ and/or CN at between about 500° C. and about 900° C. between about 760 Torr and about 1 Torr for between about 5 sec and about 400 sec.

6. A method according to claim 2 wherein annealing the sidewall of the metal nitride layer in a second nitridizing ambient comprises annealing the sidewall of the metal nitride layer in an ambient that comprises N₂O, NH₃ and He.

7. A method according to claim 6 wherein annealing the sidewall of the metal nitride layer in an ambient that comprises N₂O, NH₃ and He comprises annealing the sidewall of the metal nitride layer in an ambient that comprises N₂O, NH₃ and He at respective flow rates of 50/300/1615 seem, at about 400° C. and about 7 Torr for about 30 seconds, at an applied RF power of about 100W.

8. A method according to claim 2 wherein annealing the sidewall of the metal nitride layer in a second nitridizing ambient comprises annealing the sidewall of the metal nitride layer in an ambient that comprises N₂ and/or CN at between about 200° C. and about 500° C., between about 1 Torr and about 760 Ton for between about 10 sec and about 400 sec at an applied RF power of about 5 kW.

9. A method according to claim 2 wherein the first and second nitridizing ambients include at least one common constituent.

10. A method according to claim 1 wherein the gate insulating layer comprises silicon dioxide and/or partially nitrided oxide, wherein the metal nitride layer comprises TiN and wherein the cap comprises polysilicon.

11. An integrated circuit field effect transistor that is fabricated according to the method of claim 1.

12. An integrated circuit field effect transistor that is fabricated according to the method of claim 2.

13. A method of fabricating an integrated circuit field effect transistor gate, the method comprising:
fabricating a gate insulating layer on an integrated circuit substrate;
fabricating a metal nitride layer on the gate insulating layer;
fabricating a cap on the metal nitride layer;
etching the cap and the metal nitride layer to expose sidewalls thereof; and
annealing a sidewall of the metal nitride layer in a nitridizing ambient.

14. A method according to claim 13 wherein annealing the sidewall of the metal nitride layer in a nitridizing ambient comprises annealing the sidewall of the metal nitride layer in an ambient that comprises N₂O, NH3 and He.

15. A method according to claim 14 wherein annealing the sidewall of the metal nitride layer in an ambient that comprises N₂O, NH₃ and He comprises annealing the sidewall of the metal nitride layer in an ambient that comprises N₃O, NH₃ and He at respective flow rates of 50/300/1615 seem, at about 400° C. and about 7 Torr for about 30 seconds, at an applied RF power of about 100W.

16. A method according to claim 13 wherein annealing the sidewall of the metal nitride layer in a nitridizing ambient comprises annealing the sidewall of the metal nitride layer in an ambient that comprises N₂ and/or CN at between about 200° C. and about 500° C., between about 1 Torr and about 760 Torr for between about 10 sec and about 400 sec at an applied RF power of about 5 kW.

17. A method according to claim 13 wherein the gate insulating layer comprises silicon dioxide and/or partially nitrided oxide, wherein the metal nitride layer comprises TiN and wherein the cap comprises polysilicon.

18. An integrated circuit field effect transistor that is fabricated according to the method of claim 13.

19. A method of fabricating an integrated circuit field effect transistor gate, the method comprising:
fabricating a gate insulating layer on an integrated circuit substrate;
fabricating a metal nitride layer on the gate insulating layer;
reducing interaction between the gate insulating layer and the metal nitride layer; and
fabricating a cap on the metal nitride layer after interaction between the gate insulating layer and the metal nitride layer has been reduced.

20. A method according to claim 19, further comprising:
etching the cap and the metal nitride layer to expose sidewalls thereof; and
converting at least some metal at the exposed sidewall of the metal nitride layer back to the metal nitride.
